(19) United States
(12) Patent Application Publication
(10) Pub. No.: US 2024/0381640 A1
(43) Pub. Date: Nov. 14, 2024

(54) SEMICONDUCTOR DEVICE AND METHOD OF MANUFACTURING SEMICONDUCTOR DEVICE

(71) Applicant: SK hynix Inc., Icheon-si Gyeonggi-do (KR)

(72) Inventor: Nam Jae LEE, Icheon-si Gyeonggi-do (KR)

(73) Assignee: SK hynix Inc., Icheon-si Gyeonggi-do (KR)

(21) Appl. No.: 18/366,404

(22) Filed: Aug. 7, 2023

(30) Foreign Application Priority Data
May 9, 2023 (KR) 10-2023-0059766

(51) Int. Cl. H10B 43/27; H01L 23/522; H01L 23/528; H10B 43/10; H10B 43/40; H10B 99/00

(52) U.S. Cl. CPC H10B 43/27; H01L 23/5226; H01L 23/5283; H10B 43/10; H10B 43/40; H10B 99/14

(57) ABSTRACT

A semiconductor device may include a first semiconductor structure including a gate structure and a stack, the gate structure including channel structures and the stack including a capacitor, and a second semiconductor structure that is bonded to the first semiconductor structure, the second semiconductor structure including a peripheral circuit. The capacitor may include conductive layers and dielectric layers that are alternately stacked along an internal surface of a trench that is formed within the stack.

### CROSS-REFERENCE TO RELATED APPLICATION

This application claims priority under 35 U.S.C. § 119 (a) to Korean Patent Application No. 10-2023-0059766 filed on May 9, 2023, in the Korean Intellectual Property Office, which is incorporated herein by reference in its entirety.

### BACKGROUND

### 1. Technical Field

Embodiments relate to an electronic device and a method of manufacturing an electronic device and, more particularly, to a semiconductor device and a method of manufacturing a semiconductor device.

### 2. Related Art

The degree of integration of semiconductor devices is basically determined by the area that is occupied by a unit memory cell. As the improvement of the degree of integration of semiconductor devices in which a memory cell is formed on a substrate as a single layer has been reaching its limit, a three-dimensional semiconductor device in which memory cells are stacked on a substrate is proposed. Furthermore, in order to improve operation reliability of such a semiconductor device, various structures and manufacturing methods are being developed.

### SUMMARY

In an embodiment, a semiconductor device may include a first semiconductor structure including a gate structure and a stack, the gate structure including channel structures and the stack including a capacitor, and a second semiconductor structure that is bonded to the first semiconductor structure, the second semiconductor structure including a peripheral circuit. The capacitor may include conductive layers and dielectric layers that are alternately stacked along an internal surface of a trench that is formed within the stack.

In an embodiment, a semiconductor device may include a stack including sacrificial layers and insulating layers that are alternately stacked, a contact plug that extends through the stack, a first capacitor that is disposed within the stack, the first capacitor including first conductive layers and first dielectric layers that are alternately stacked, a second capacitor that is disposed within the stack, the second capacitor including second conductive layers and second dielectric layers that are alternately stacked, and an interconnection structure that connects the first capacitor and the second capacitor in parallel.

In an embodiment, a method of manufacturing a semiconductor device may include forming a stack including first material layers and second material layers that are alternately stacked over a substrate, forming a first trench within the stack, forming, within the stack, a second trench having a width that is different from the width of the first trench, forming a first conductive layer within the first trench and the second trench, alternately stacking second conductive layers and dielectric layers within the second trench, and forming a contact plug within the first trench and a capacitor within the second trench by planarizing the first conductive layer, the second conductive layers, and the dielectric layers.

In an embodiment, a method of manufacturing a semiconductor device may include forming a stack over a substrate, forming channel structures that extend into the substrate through the stack, forming a first trench that extends into the substrate through the stack, forming a second trench that extends into the substrate through the stack, forming a contact plug within the first trench by forming a first conductive layer within the first trench and the second trench, forming a first capacitor by alternately stacking second conductive layers and dielectric layers within the second trench, removing the substrate so that the channel structures, the contact plug, and the first capacitor are exposed, and forming a source structure that is connected to the channel structures.

### BRIEF DESCRIPTION OF THE DRAWINGS

FIG. 1 is a diagram illustrating a semiconductor device according to an embodiment of the present disclosure.

FIGS. 2A, 2B, and 2C are diagrams illustrating a semiconductor device according to an embodiment of the present disclosure.

FIG. 3 is a diagram illustrating a semiconductor device according to an embodiment of the present disclosure.

FIGS. 4A to 4E are diagrams illustrating a method of manufacturing a semiconductor device according to an embodiment of the present disclosure.

FIGS. 5A to 5E are diagrams illustrating a method of manufacturing a semiconductor device according to an embodiment of the present disclosure.

### DETAILED DESCRIPTION

Hereinafter, embodiments according to the technical spirit of the present disclosure are described with reference to the accompanying drawings.

Embodiments of the present disclosure provide a semiconductor device having a stable structure and an improve characteristic and a method of manufacturing a semiconductor device.

According to the present technology, it is possible to provide the semiconductor device having a stable structure and improved reliability.

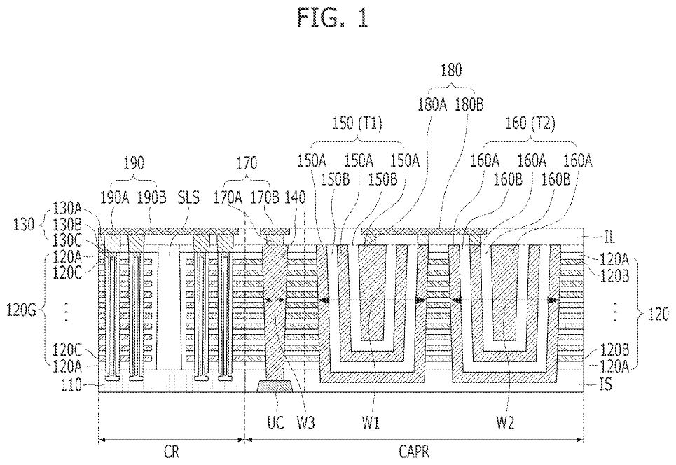

FIG. 1 is a diagram illustrating a semiconductor device according to an embodiment of the present disclosure.

Referring to FIG. 1, the semiconductor device may include a source structure 110, a stack 120, a gate structure 120G, channel structures 130, a contact plug 140, a first capacitor 150, a second capacitor 160, or a combination thereof. The semiconductor device may further include a first interconnection structure 170, a second interconnection structure 180, a third interconnection structure 190, a slit structure SLS, an insulating layer IS, an insulating layer IL, or a combination thereof.

The semiconductor device may include a cell region CR and a capacitor region CAPR. The cell region CR may be a region in which stacked memory cells are disposed. For example, a cell array including memory strings may be disposed in the cell region CR. The capacitor region CAPR may be a region in which the first capacitor 150 or the second capacitor 160 is disposed. The contact plug 140 may be electrically connected to a peripheral circuit that is disposed under the cell region CR and the capacitor region CAPR.

The gate structure 120G may be disposed on the source structure 110. The gate structure 120G and the source structure 110 may be disposed in the cell region CR. The gate structure 120G may include insulating layers 120A and conductive layers 120C that are alternately stacked. The conductive layers 120C may include a word line and a selection line. The insulating layers 120A may each include an insulating material, such as oxide. The conductive layers 120C may each include a conductive material, such as tungsten or molybdenum.

The stack 120 may be disposed in the capacitor region CAPR. The stack 120 may be disposed on the insulating layer IS. The stack 120 may be disposed substantially at the same level as the gate structure 120G. The stack 120 may include sacrificial layers 120B and insulating layers 120A that are alternately stacked. The sacrificial layers 120B may be disposed at levels corresponding to the conductive layers 120C, respectively. The sacrificial layers 120B may remain without being substituted with the conductive layers 120C in a process of manufacturing the semiconductor device. The sacrificial layers 120B may each include a sacrificial material, such as nitride. The insulating layers 120A may each include an insulating material, such as oxide.

The slit structure SLS may be disposed within the gate structure 120G. The slit structure SLS may be disposed between the channel structures 130. The slit structure SLS may be a structure in which an insulating material, a conductive material or a semiconductor material, has been formed within a slit (not illustrated). The slit (not illustrated) may be used as a passageway for substituting some of the sacrificial layers 120B of the stack 120 with the conductive layers 120C in a process of manufacturing the semiconductor device. Accordingly, the gate structure 120G including the conductive layers 120C may be defined in the cell region CR.

The channel structures 130 may be disposed within the gate structure 120G. The channel structures 130 may extend into the source structure 110 through the gate structure 120G. The channel structures 130 may each include a channel layer 130A, a memory layer 130B that surrounds the channel layer 130A, an insulating core 130C within the channel layer 130A, or a combination thereof. The channel structures 130 may be connected to the source structure 110. For example, the channel layer 130A and the source structure 110 may be directly connected or may be connected through an epitaxial pattern.

The first capacitor 150 and the second capacitor 160 may be disposed within the stack 120. The first capacitor 150 may be disposed within the stack 120 and may include first conductive layers 150A and first dielectric layers 150B that are alternately stacked. The second capacitor 160 may be disposed within the stack 120 and may include second conductive layers 160A and second dielectric layers 160B that are alternately stacked. In this case, the conductive layers 150A and 160A may each include a conductive material, such as tungsten or molybdenum. The dielectric layers 150B and 160B may each include an insulating material, such as oxide. For example, the conductive layers 150A and 160A may each include molybdenum, and the dielectric layers 150B and 160B may each include oxide.

The capacitors 150 and 160 may include the conductive layers 150A and 160A and the dielectric layers 150B and 160B that are alternately stacked along internal surfaces of trenches T1 and T2, respectively, which are formed within the stack 120. Since the conductive layers 150A and 160A and the dielectric layers 150B and 160B are alternately formed along the internal surfaces of the trenches T1 and T2, the widths of the trenches T1 and T2 and the thicknesses of the conductive layers 150A and 160A and the dielectric layers 150B and 160B may be adjusted by considering the capacities of the capacitors 150 and 160. Accordingly, the thicknesses of the conductive layers 150A and 160A and the dielectric layers 150B and 160B can be uniformly formed, and the capacitance of the capacitors 150 and 160 can be increased.

The thickness of each of the conductive layers 150A and 160A may be substantially the same as or different from the thickness of each of the dielectric layers 150B and 160B. For example, the thickness of each of the conductive layers 150A and 160A may be substantially the same as the thickness of each of the dielectric layers 150B and 160B. The thickness of each of the conductive layers 150A and 160A and each of the dielectric layers 150B and 160B may be 300 to 600 Å. For example, the thickness of each of the conductive layers 150A and 160A and each of the dielectric layers 150B and 160B may be 450 Å. The thicknesses of the dielectric layers 150B and 160B may be determined by considering breakdown voltages of the conductive layers 150A and 160A, respectively. Since each of the dielectric layers 150B and 160B is formed to a minimum thickness by considering the breakdown voltage, the numbers of conductive layers 150A and 160A that are formed within the trenches T1 and T2 can be increased. Accordingly, the capacitance of the capacitors 150 and 160 can be increased.

The capacitors 150 and 160 may include the conductive layers 150A and 160A and the dielectric layers 150B and 160B, respectively, which are alternately stacked. Each of the conductive layers 150A and 160A may be an electrode that constitutes each of the capacitors 150 and 160. Accordingly, by increasing the number of conductive layers 150A and 160A that are formed within the trenches T1 and T2, the number of electrodes that are included in the capacitors 150 and 160 can be increased, and the capacitance of the capacitors 150 and 160 can be increased.

The capacitors 150 and 160 may each have a tapered form, and may have a first width W1 and a second width W2, respectively. In other words, the first width W1 and the second width W2 may be different based on a height at which the widths are measured. For example, the first width W1 and the second width W2 may be greater when measured at an upper surface of the capacitors 150 and 160, respectively, compared to when measured at a lower surface of the capacitors 150 and 160, respectively. The first width W1 and the second width W2 may be different widths or may be substantially the same. For example, the first width W1 and the second width W2 may be substantially the same when measured at the same height.

The contact plug 140 may extend through the stack 120. For example, the contact plug 140 may extend into the insulating layer IS through the stack 120 and may be connected to a wire UC that is connected to the peripheral circuit. The contact plug 140 may have a tapered form and may have a third width W3. In other words, the third width W3 may be different based on a height at which the width is measured. For example, the third width W3 may be greater when measured at an upper surface of the contact plug 140 compared to when measured at a lower surface of the contact plug 140. The third width W3 may be different from the first width W1 or the second width W2 or may be substantially the same as the first width W1 or the second width W2 when measured at the same height. For example, the third width W3 may be less than each of the first width W1 and the second width W2 when measured at the same height. Accordingly, the third width W3 of the contact plug 140 may be less than the width W1 or W2 of the capacitor 150 or 160 when measured at the same height.

The contact plug 140 may have a height that is different from or substantially the same as the height of each of the capacitor 150 and 160. For example, the contact plug 140 may have substantially the same height as each of the capacitors 150 and 160. The contact plug 140 may include a material that is substantially the same as or different from the material of the conductive layers 150A and 160A of the capacitors 150 and 160. The contact plug 140 may include a conductive material, such as tungsten or molybdenum. For example, the contact plug 140 may include molybdenum.

For reference, although not illustrated in the drawing, the peripheral circuit may be included under the source structure 110. The contact plug 140 may be connected to the peripheral circuit that is disposed under the source structure 110. For example, the contact plug 140 may extend through the stack 120 and may be connected to the peripheral circuit.

At least one of the first interconnection structure 170 and the second interconnection structure 180 may be disposed on the stack 120. The third interconnection structure 190 may be disposed on the gate structure 120G. The first interconnection structure 170 may include at least one of a first contact via 170A and a first wire 170B. The second interconnection structure 180 may include at least one of second contact vias 180A and a second wire 180B. The third interconnection structure 190 may include at least one of third contact vias 190A and a third wire 190B.

The first interconnection structure 170 may be disposed on the contact plug 140 and may be electrically connected to the contact plug 140. For example, the first contact via 170A may be disposed on the contact plug 140 and may be connected to the contact plug 140. Furthermore, the first wire 170B may be disposed on the first contact via 170A and may be connected to the first contact via 170A.

The second interconnection structure 180 may be disposed on the capacitors 150 and 160 and may be electrically connected to the capacitors 150 and 160. For example, the second contact vias 180A may be disposed on the capacitors 150 and 160 and may be connected to at least one of the conductive layers 150A and 160A. Furthermore, the second wire 180B may be disposed on the second contact vias 180A and may be connected to at least one of the second contact vias 180A.

The first contact via 170A and the second contact vias 180A may have substantially the same height or may have different heights. For example, the first contact via 170A and the second contact vias 180A may have substantially the same height. Furthermore, the first wire 170B and the second wire 180B may have substantially the same height or may have different heights. For example, the first wire 170B and the second wire 180B may have substantially the same height.

The third interconnection structure 190 may be disposed on the channel structures 130 and may be electrically connected to the channel structures 130. For example, the third contact vias 190A may be disposed on the channel structures 130 and may be connected to at least one of the channel structures 130. Furthermore, the third wire 190B may be disposed on the third contact vias 190A and may be connected to at least one of the third contact vias 190A.

In this case, the first interconnection structure 170, the second interconnection structure 180, and the third interconnection structure 190 may be disposed within the insulating layer IL. The insulating layer IL may be disposed on the stack 120 and the gate structure 120G. The insulating layer IL may each include an insulating material, such as oxide.

According to the aforementioned structure, the thicknesses of the conductive layers 150A and 160A and the dielectric layers 150B and 160B may be determined by considering the capacitance of the capacitors 150 and 160. The number of conductive layers 150A and 160A that are formed within the trenches T1 and T2 may be increased by minimizing the thicknesses of the dielectric layers 150B and 160B. Accordingly, the capacitance of the capacitors 150 and 160 can be increased.

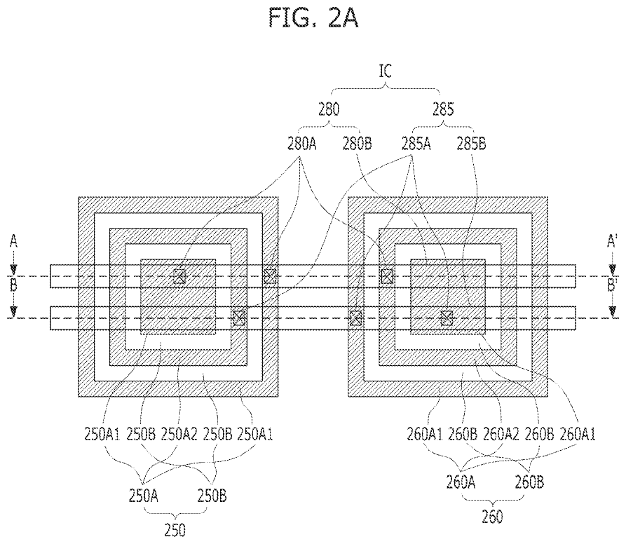

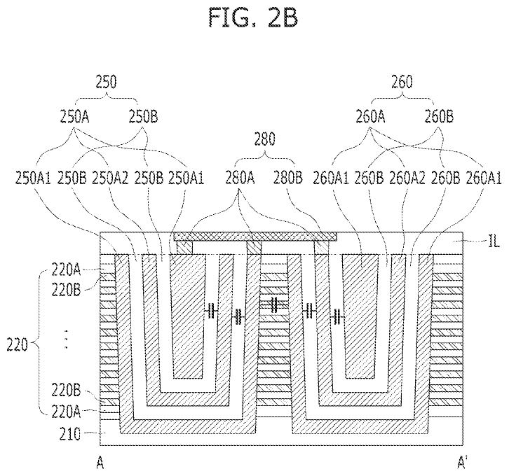

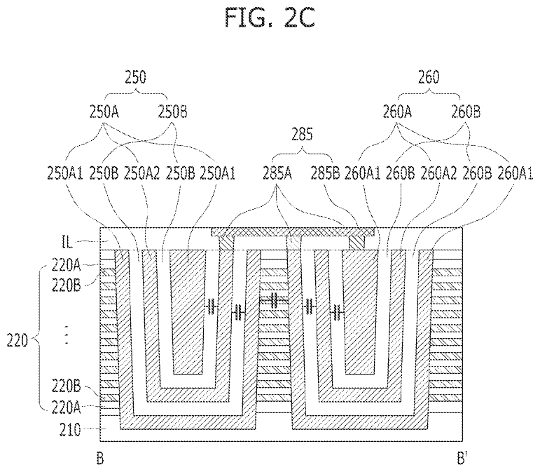

FIGS. 2A, 2B, and 2C are diagrams illustrating a semiconductor device according to an embodiment of the present disclosure. FIG. 2A may be a plan view of the first capacitor 150 and the second capacitor 160B in FIG. 1A. FIG. 2B may be a cross-sectional view taken along line A-A′ in FIG. 2A. FIG. 2C may be a cross-sectional view taken along line B-B′ in FIG. 2A. Hereinafter, a description of contents redundant with the aforementioned contents has been omitted.

Referring to FIGS. 2A to 2C, the semiconductor device may include a stack 220, a first capacitor 250, a second capacitor 260, or a combination thereof. The semiconductor device may further include an insulating layer 210, an insulating layer IL, an interconnection structure IC, or a combination thereof.

The first capacitor 250 may be disposed within the insulating layer 210 through the stack 220 and may include first conductive layers 250A and first dielectric layers 250B that are alternately stacked. In this case, the first conductive layers 250A may include an odd first conductive layer 250A1 and an even first conductive layer 250A2. The second capacitor 260 may be disposed within the insulating layer 210 through the stack 220 and may include second conductive layers 260A and second dielectric layers 260B that are alternately stacked. In this case, the second conductive layers 260A may include an odd second conductive layer 260A1 and an even second conductive layer 260A2. The stack 220 may include insulating layers 220A and sacrificial layers 220B that are alternately stacked.

The interconnection structure IC may be disposed within the insulating layer IL. In this case, the insulating layer IL may be disposed on the stack 220. The interconnection structure IC may include a first interconnection structure 280, a second interconnection structure 285, or a combination thereof. The first interconnection structure 280 may include first contact vias 280A, a first wire 280B, or a combination thereof. The second interconnection structure 285 may include second contact vias 285A, a second wire 285B, or a combination thereof. The first contact vias 280A and the second contact vias 285A may be disposed to be spaced apart from each other. The first wire 280B and the second wire 285B may be disposed to be spaced apart from each other.

The first capacitor 250 and the second capacitor 260 may be connected in parallel by the interconnection structure IC. The first contact vias 280A may be disposed on the capacitors 250 and 260 and may be connected to at least one of the first conductive layers 250A and the second conductive layers 260A. The first wire 280B may be disposed on the first contact vias 280A and may be connected to at least one of the first contact vias 280A. The first wire 280B may be electrically connected to the capacitors 250 and 260 through the first contact vias 280A.

The second contact vias 285A may be disposed on the capacitors 250 and 260 and may be connected to at least one of the first conductive layers 250A and the second conductive layers 260A. The second wire 285B may be disposed on the second contact vias 285A and may be connected to at least one of the second contact vias 285A. The second wire 285B may be electrically connected to the capacitors 250 and 260 through the second contact vias 285A.

For example, the first wire 280B may be connected to the odd first conductive layer 250A1 and the even second conductive layer 260A2. The second wire 285B may be connected to the even first conductive layer 250A2 and the odd second conductive layer 260A1. In another example, the first wire 280B may be connected to the even first conductive layer 250A2 and the odd second conductive layer 260A1. The second wire 285B may be connected to the odd first conductive layer 250A1 and the even second conductive layer 260A2. In other words, the wires 280B and 285B may be electrically connected to the odd first conductive layer 250A1 of the first capacitor 250 and the even second conductive layer 260A2 of the second capacitor 260, respectively, or may be electrically connected to the second even conductive layer 250A2 of the first capacitor 250 and the odd first conductive layer 260A1 of the second capacitor 260, respectively. Accordingly, the first capacitor 250 and the second capacitor 260 may be electrically connected in parallel.

For reference, terms “over and under” and “top and bottom” that are described in this specification may be relative concepts. For example, the capacitors 250 and 260 that are disposed within the stack 220 may be upside down compared to the capacitors 150 and 160 in FIG. 1. In this case, the contact vias 280A and 285A and the wires 280B and 285B may be disposed under the capacitors 250 and 260 and may be disposed under the stack 220.

According to the aforementioned structure, the storage capacity of the capacitors 250 and 260 can be increased compared to a case in which each of the capacitors 250 and 260 is connected in series because the plurality of capacitors 250 and 260 is connected in parallel.

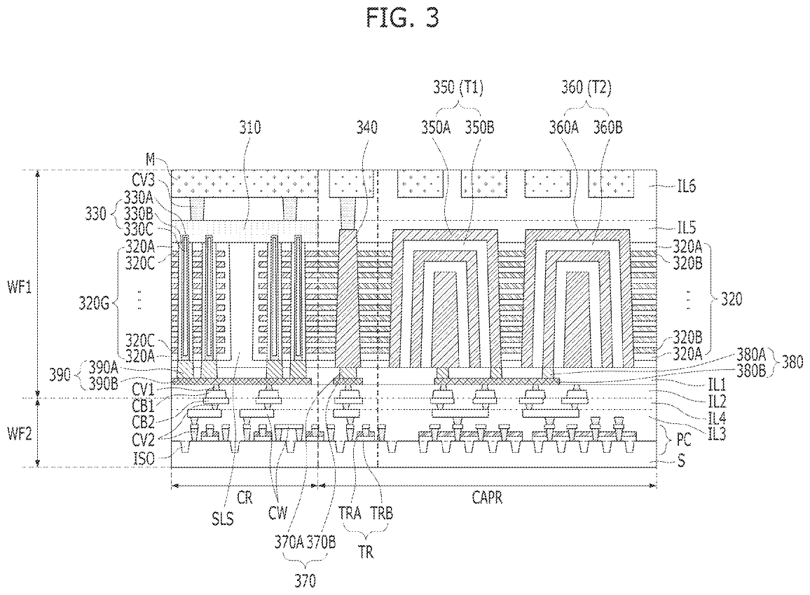

FIG. 3 is a diagram illustrating a semiconductor device according to an embodiment of the present disclosure. Hereinafter, a description of contents redundant with the aforementioned contents has been omitted.

Referring to FIG. 3, the semiconductor device may include a first wafer WF1, a second wafer WF2, or a combination thereof. In this case, the first wafer WF1 may mean a first semiconductor structure that includes or does not include a substrate. For example, the first wafer WF1 may mean a first semiconductor structure that includes a source structure 310, a stack 320, a gate structure 320G, channel structures 330, a contact plug 340, a first capacitor 350, a second capacitor 360, a first interconnection structure 370, a second interconnection structure 380, a slit structure SLS, insulating layers IL1, IL2, IL5, and IL6, or a combination thereof. The first wafer WF1 may further include a metal wire M, connection vias CV1 and CV3, a first bonding pad CB1, or a combination thereof.

The stack 320 may include insulating layers 320A and sacrificial layers 320B that are alternately stacked. The gate structure 320G may include the insulating layers 320A and conductive layers 320C that are alternately stacked. The capacitors 350 and 360 may include conductive layers 350A and 360A and dielectric layers 350B and 360B, respectively, which are alternately stacked. The interconnection structures 370, 380, and 390 may include contact vias 370A, 380A, and 390A or wires 370B, 380B, and 390B, respectively, and may be disposed within the insulating layer IL1.

The second wafer WF2 may mean a second semiconductor structure that includes or does not include a substrate. For example, the second wafer WF2 may mean a second semiconductor structure that includes a substrate S, a peripheral circuit PC, a connection via CV2, a second bonding pad CB2, or a combination thereof. The second wafer WF2 may further include insulating layers IL3 and IL4, an isolation insulating layer ISO, or a combination thereof.

The second wafer WF2 may include the peripheral circuit PC. The peripheral circuit PC may be disposed on the substrate S. The isolation insulating layer ISO may be disposed within the substrate S. The peripheral circuit PC may include a transistor TR, a capacitor, a register, or an input and output circuit. The input and output circuit may be a circuit that transmits and receives signals to and from an external device and may include the transistor TR. The transistor TR may include junctions, a gate insulating layer TRB, or a gate electrode TRA. The gate insulating layer TRB may be disposed between the gate electrode TRA and the substrate S. The gate insulating layer TRB and the isolation insulating layer ISO may each include an insulating material, such as oxide or nitride.

The insulating layers IL3 and IL4 may be disposed on the substrate S. The connection via CV2 and a connection wire CW may be disposed within the insulating layers IL3 and IL4. The connection via CV2 and the connection wire CW may be electrically connected to the peripheral circuit PC. The connection via CV2 may connect the junction of the transistor with the junction of the connection wire CW or may connect the connection wire CW with the second bonding pad CB2. The connection wire CW may connect the connection vias CV2. The connection via CV2 and the connection wire CW may each include a conductive material, such as tungsten.

The second bonding pad CB2 may be disposed on the substrate S. The second bonding pad CB2 may be disposed within the insulating layer IL4. The second bonding pad CB2 may be electrically connected to the peripheral circuit PC through the connection via CV2 and the connection wire CW. The second bonding pad CB2 may include a conductive material, such as copper.

The first wafer WF1 and the second wafer WF2 may be bonded. The top of the first wafer WF1 and the top of the second wafer WF2 may be bonded. Accordingly, as the first wafer WF1 and the second wafer WF2 are bonded, the first wafer WF1 may include the channel structures 330, the contact plug 340, and the capacitors 350 and 360 being upside down compared to the capacitors 150 and 160 of FIG. 1.

The first bonding pad CB1 of the first wafer WF1 and the second bonding pad CB2 of the second wafer WF2 may be bonded. The first bonding pad CB1 may be formed over the gate structure 320G and the stack 320 and may be disposed under the gate structure 320G and the stack 320 after bonding. The first bonding pad CB1 may be disposed within the insulating layer IL2. The first bonding pad CB1 may be electrically connected to the interconnection structures 370, 380, and 390 through the connection via CV1.

The connection via CV1 may be disposed within the insulating layer IL2. The insulating layer IL2 may be disposed over or under the insulating layer IL1. For example, the connection via CV1 may be formed on the insulating layer IL1. After bonding, the connection via CV1 may be disposed below the insulating layer IL1. Hereinafter, a case in which the top of the first wafer WF1 and the top of the second wafer WF2 have been bonded is assumed and described.

The source structure 310 may be disposed on the gate structure 320G and may be connected to the channel structures 330. In this case, the gate structure 320G may include the insulating layers 320A and the conductive layers 320C that are alternately stacked. The channel structures 330 may include the channel layer 320A, the memory layer 320B, or the insulating core 320C. The source structure 310 may be directly connected to the channel layer 330A or may be connected to the channel layer 330A through an epitaxial pattern.

The metal wire M may be disposed on the gate structure 320G and the stack 320. The metal wire M may be electrically connected to the source structure 310 or the contact plug 340 through the connection via CV3. For example, the connection via CV3 may be disposed on the source structure 310 and may connect the source structure 310 with the metal wire M. Furthermore, the connection via CV3 may be disposed on the contact plug 340 and may connect the contact plug 340 with the metal wire M. The metal wire M or the connection via CV3 may be disposed within the insulating layer IL5 and IL6. The metal wire M or the connection via CV3 may include a conductive material, such as aluminum or tungsten. The insulating layer IL5 may be disposed on the stack 320. The insulating layer IL6 may be disposed on the insulating layer IL5. The metal wire M may include a conductive material, such as aluminum.

The contact plug 340 may extend through the stack 320 and may be electrically connected to the peripheral circuit PC of the first wafer WF1. The contact plug 340 may have substantially the same height as the capacitors 350 and 360. The contact plug 340 may include a material that is substantially the same as or different from the material of the conductive layers 350A and 360A of the capacitors 350 and 360. The contact plug 340 may include a conductive material, such as tungsten or molybdenum. For example, the contact plug 340 may include molybdenum.

The capacitors 350 and 360 may be disposed to face the peripheral circuit PC. For example, the capacitors 350 and 360 may be disposed to face the input and output circuit. Accordingly, a distance between the capacitors 350 and 360 and the input and output circuit can be reduced because the capacitors 350 and 360 and the input and output circuit are bonded to face each other when the first wafer WF1 and the second wafer WF2 are bonded.

According to the aforementioned structure, the first wafer WF1 may include the memory cell array and the capacitors 350 and 360 because the capacitors 350 and 360 are disposed within the stack 320.

Furthermore, the conductive layers 350A and 360A and the dielectric layers 350B and 360B can be alternately stacked within the trenches T1 and T2 by considering the capacitance of the capacitors 350 and 260. The number of conductive layers 350A and 360A can be increased by minimizing the thicknesses of the dielectric layers 350B and 360B. Accordingly, the capacitance of the capacitors 350 and 360 can be increased.

The first wafer WF1 including the channel structures 330 and the capacitors 350 and 360 may be bonded to the second wafer WF2 including the peripheral circuit PC. The contact plug 340 may be electrically connected to the peripheral circuit PC. The capacitors 350 and 360 may be bonded to face the input and output circuit of the peripheral circuit PC. Accordingly, the length of a voltage supply path between the input and output circuit and the capacitors 350 and 360 can be reduced.

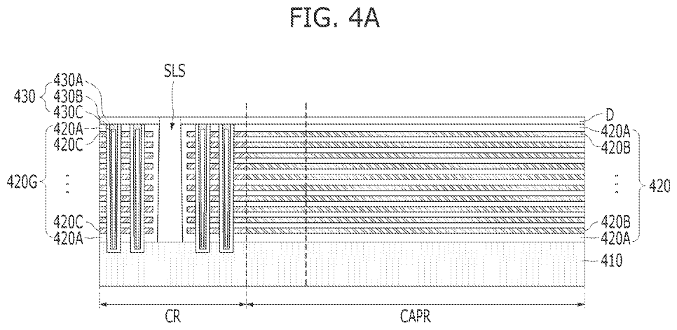

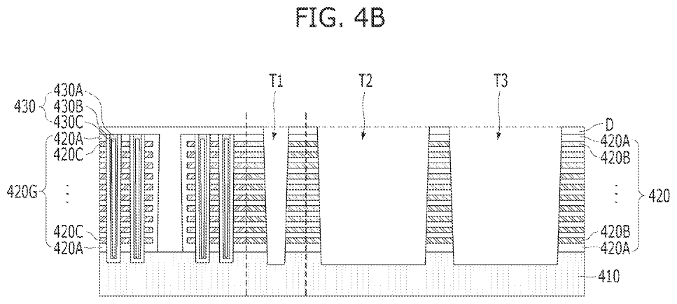

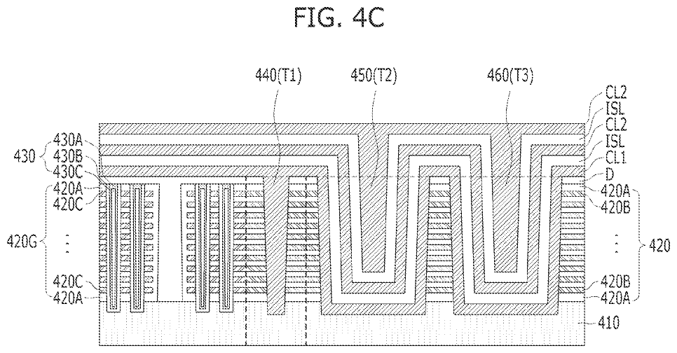

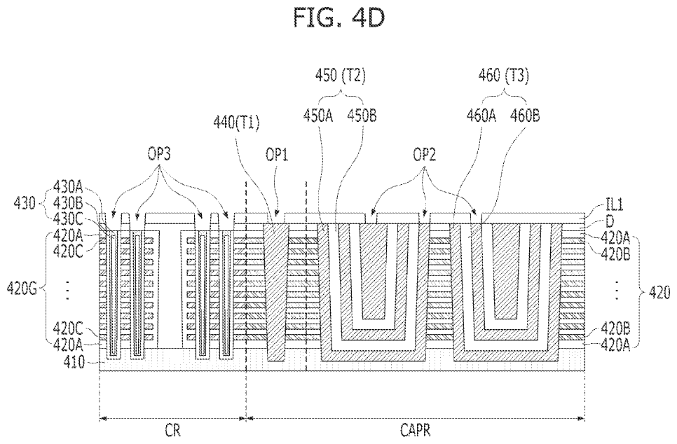

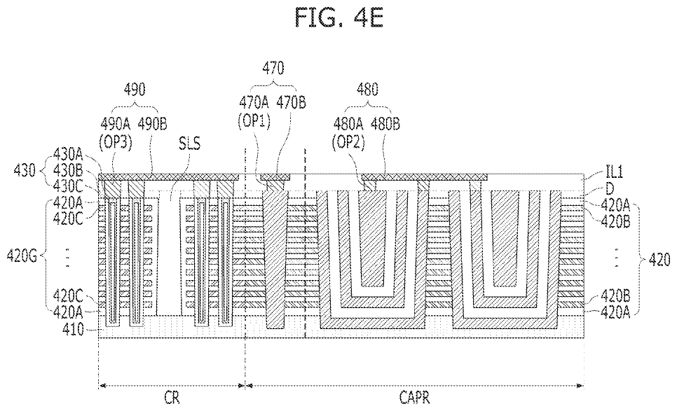

FIGS. 4A to 4E are diagrams illustrating a method of manufacturing a semiconductor device according to an embodiment of the present disclosure. Hereinafter, a description of contents redundant with the aforementioned contents has been omitted.

Referring to FIG. 4A, a stack 420 may be formed on a substrate 410. In this case, the substrate 410 may include a cell region CR and a capacitor region CAPR. The cell region CR may be a region in which stacked memory cells will be formed. The capacitor region CAPR may be a region in which a contact plug or capacitors that are connected to a peripheral circuit disposed under the substrate 410 will be formed. The stack 420 may be formed in the capacitor region CAPR and may be extended up to the cell region CR. The stack 420 may include first material layers 420A and second material layers 420B that are alternately stacked. In this case, the first material layers 420A may each include an insulating material, such as oxide. The second material layers 420B may include a sacrificial material, such as nitride.

Next, channel structures 430 may be formed within the stack 420 of the cell region CR. For example, the channel structures 430, each one including the channel layer 420A and the memory layer 420B that surrounds the channel layer 420A, may be formed within the stack 420. The channel structures 430 may extend into the substrate 410 through the stack 420. The channel structures 430 may each include an insulating core 420C within the channel layer 420A.

Next, a slit may be formed within the stack 420. For example, the slit that extends through the stack 420 may be formed in the cell region CR. Next, a gate structure 420G may be formed by substituting the second material layers 420B of the stack 420 with third material layers 420C, respectively, through the slit. For example, the gate structure 420G may be formed by substituting the second material layers 420B of the stack 420 of the cell region CR with the third material layers 420C. In this case, the third material layers 420C may each include a conductive material, such as tungsten or molybdenum. The stack 420 of the capacitor region CAPR may remain. Next, the slit structure SLS may be formed within the slit. For example, a slit structure SLS may be formed by forming an insulating material D along internal surfaces of the stack 420 and the gate structure 420G. In this case, the insulating material D may include oxide. However, it is not limited thereto, and a conductive material or a semiconductor material may be formed instead of the insulating material D.

Referring to FIG. 4B, a first trench T1 may be formed within the stack 420. The first trench T1 may be formed within the stack 420 of the capacitor region CAPR. The first trench T1 may extend into the substrate 410 through the stack 420.

A second trench T2 or a third trench T3 may be formed within the stack 420. The second trench T2 or the third trench T3 may be formed within the stack 420 of the capacitor region CAPR. When the first trench T1 is formed, at least one of the second trench T2 and the third trench T3 may be formed. The width of at least one of the second trench T2 and the third trench T3 may be substantially the same as or different from the width of the first trench T1 when measured at the same height. For example, the width of at least one of the second trench T2 and the third trench T3 may be greater than the first trench T1 when measured at the same height. Furthermore, the height of at least one of the second trench T2 and the third trench T3 may be substantially the same as or different from the height of the first trench T1. For example, the height of at least one of the second trench T2 and the third trench T3 may be substantially the same as the height of the first trench T1.

A manufacturing process of the semiconductor device can be simplified because the first trench T1 and the second trench T2 or the third trench T3 having a different width than the first trench T1 are formed simultaneously.

Referring to FIGS. 4C and 4D, a first conductive layer CL1 may be formed within the first trench T1, the second trench T2, and the third trench T3. In this case, the first conductive layer CL1 may be formed to fill the first trench T1 having a narrower width than each of the trenches T2 and T3 and may be formed along internal surfaces of the second trench T2 and the third trench T3 so that parts of the second trench T2 and the third trench T3 are filled. Next, second conductive layers CL2 and dielectric layers ISL may be alternately stacked within the second trench T2 and the third trench T3. In this case, the conductive layers CL1 and CL2 may each include a conductive material, such as tungsten or molybdenum. The dielectric layers ISL may each include an insulating material, such as oxide.

A contact plug 440 may be formed within the first trench T1. A first capacitor 450 may be formed within the second trench T2. A second capacitor 460 may be formed within the third trench T3. For example, by planarizing the first conductive layer CL1 and the second conductive layers CL2, the contact plug 440 may be formed within the first trench T1, the first capacitor 450 may be formed within the second trench T2, and the second capacitor 460 may be formed within the third trench T3. In this case, the first conductive layer CL1 and second conductive layers CL2 of the first capacitor 450 may be defined as first conductive layers 450A. The dielectric layers ISL may be defined as first dielectric layers 450B. The first conductive layer CL1 and second conductive layers CL2 of the second capacitor 460 may be defined as second conductive layers 460A. The dielectric layers 460B may be defined as second dielectric layers 460B.

The contact plug 440 may be first formed within the first trench T1 by forming the first conductive layer CL1 within the first trench T1 and the trenches T2 and T3. The first conductive layer CL1 that is formed within the trenches T2 and T3 may be used as electrodes of the capacitors 450 and 460. The number of electrodes can be increased by stacking the second conductive layers CL2 within the trenches T2 and T3.

In other words, the capacitors 450 and 460 may include the conductive layers 450A and 460A and the dielectric layers 450B and 460B, respectively, which are alternately stacked. The conductive layers 450A and 460A may be electrodes that constitute the capacitors 450 and 460, respectively. Accordingly, by increasing the number of conductive layers 450A and 460A that are formed within the trenches T2 and T3, the number of electrodes that are included in the capacitors 450 and 460 can be increased, and the capacitance of the capacitors 450 and 460 can be increased.

Next, an insulating layer IL1 may be formed on the contact plug 440 and the capacitors 450 and 460. Next, a first opening OP1 that exposes the contact plug 440 may be formed. For example, the contact plug 440 may be exposed by forming the first opening OP1 within the insulating layer IL1.

Second openings OP2 that expose the conductive layers 450A and 460A of the capacitors 450 and 460 may be formed. For example, the conductive layers 450A and 460A may be exposed by forming the second openings OP2 within the insulating layer IL1. In this case, when the first opening OP1 is formed, the second openings OP2 may be formed.

The insulating layer IL1 may be extended on the channel structures 430 of the cell region CR. Third openings OP3 that expose the channel structures 430 may be formed. For example, the channel structures 430 may be exposed by forming the third openings OP3 within the insulating layer IL1. In this case, when the third openings OP3 are formed, at least one of the first opening OP1 and the second opening OP2 may be formed.

Referring to FIG. 4E, a first contact via 470A may be formed within the first opening OP1. Second contact vias 480A may be formed within the second openings OP2, respectively. Third contact vias 490A may be formed within the third openings OP3, respectively. The first contact via 470A may be connected to the contact plug 440. The second contact vias 480A may be connected to at least one of the first conductive layers 450A and at least one of the second conductive layers 460A. The third contact vias 490A may be connected to the channel structures 430, respectively. When the first contact via 470A is formed, the second contact vias 480A may be formed. Furthermore, when the first contact via 470A is formed, the third contact vias 490A may be formed. The first contact via 470A, the second contact vias 480A, and the third contact vias 490A may be formed within the insulating layer IL1 and may each include a conductive material, such as tungsten.

Next, a first wire 470B may be formed on the first contact via 470A. Accordingly, a first interconnection structure 470 including the first contact via 470A and the first wire 470B may be formed. A second wire 480B that is connected to at least one of the second contact vias 480A may be formed. Accordingly, a second interconnection structure 480 including the second contact via 480A and the second wire 480B may be formed. A third wire 490B that is connected to at least one of the third contact vias 490A may be formed. Accordingly, a third interconnection structure 490 including the third contact via 490A and the third wire 490B may be formed. When the first wire 470B is formed, the second wire 480B may be formed. When the first wire 470B is formed, the third wire 490B may be formed. The first wire 470B, the second wire 480B, and the third wire 490B may be formed within the insulating layer IL1 and may each include a conductive material, such as tungsten.

Referring back to FIGS. 2A to 2C, a case in which the first capacitor 450 and the second capacitor 460 are electrically connected in parallel is described. The first conductive layers 450A of the first capacitor 450 may include an odd first conductive layer and an even first conductive layer. The first conductive layers 460A of the second capacitor 460 may include an odd second conductive layer and an even second conductive layer.

The first capacitor 450 and the second capacitor 460 may be connected in parallel by the second interconnection structure 480. The second contact vias 480A may be disposed on the capacitors 450 and 460 and may be connected to at least one of the first conductive layers 450A and at least one of the second conductive layers 460A. The second wire 480B may be disposed on the second contact vias 480A and may be connected to at least one of the second contact vias 280A.

For example, the second wire 480B may connect the odd first conductive layer of the first capacitor 450 with the even second conductive layer of the second capacitor 460. In another example, the second wire 480B may connect the even first conductive layer of the first capacitor 450 with the odd second conductive layer of the second capacitor 460. In other words, the first capacitor 450 and the second capacitor 460 may be electrically connected in parallel by the second wire 480B.

For reference, although not illustrated in the drawings, an additional wire for the parallel connection of the capacitors 450 and 460 may be formed in addition to the second wire 480B. For example, if the second wire 480B connects the odd first conductive layer of the first capacitor 450 with the even second conductive layer of the second capacitor 460, an additional wire may connect the even first conductive layer of the first capacitor 450 with the odd second conductive layer of the second capacitor 460. In this case, the second wire 480B and the additional wire may be electrically connected by an interconnection structure.

Furthermore, for reference, although not illustrated in the drawings, at least one of the channel structures 430, the contact plug 440, and the capacitors 450 and 460 may be exposed by removing the substrate 410. Next, a source structure that is connected to the channel structures 430 may be formed. In this case, the channel structures 430 may be directly connected to the source structure or may be connected to the source structure through an epitaxial pattern. Furthermore, the contact plug 440 may be connected to the peripheral circuit.

According to the aforementioned manufacturing method, the contact plug 440 and the capacitors 450 and 460 may be simultaneously formed. Accordingly, manufacturing costs for the semiconductor device can be reduced. Furthermore, the capacitance of the capacitors 450 and 460 can be increased because the plurality of capacitors 450 and 460 are connected in parallel.

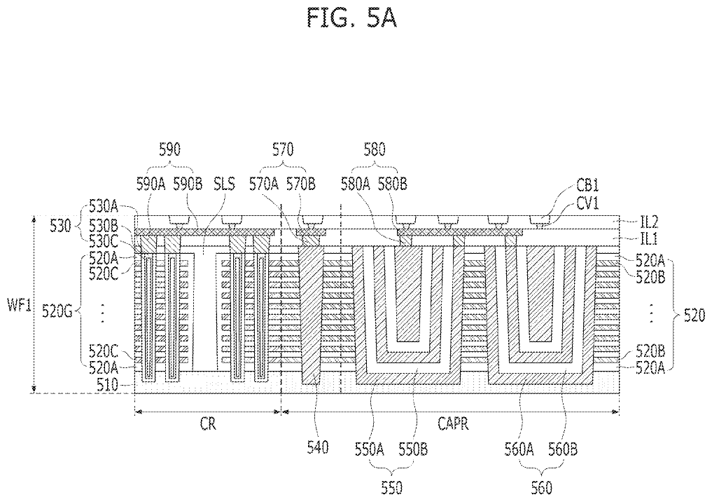

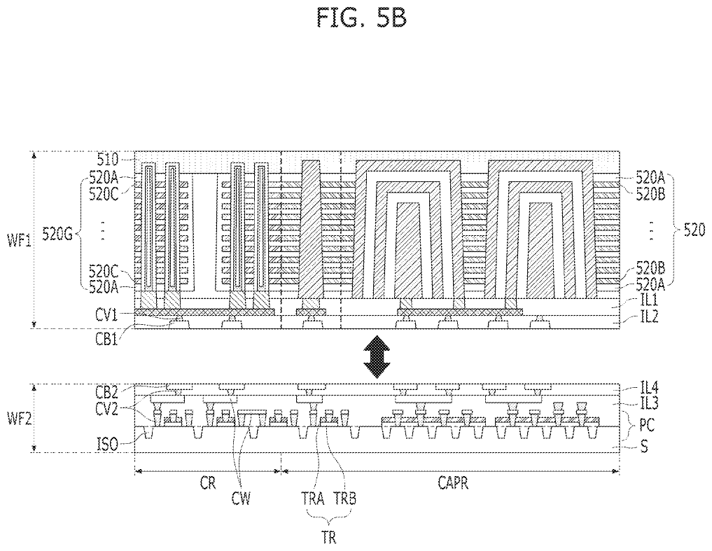

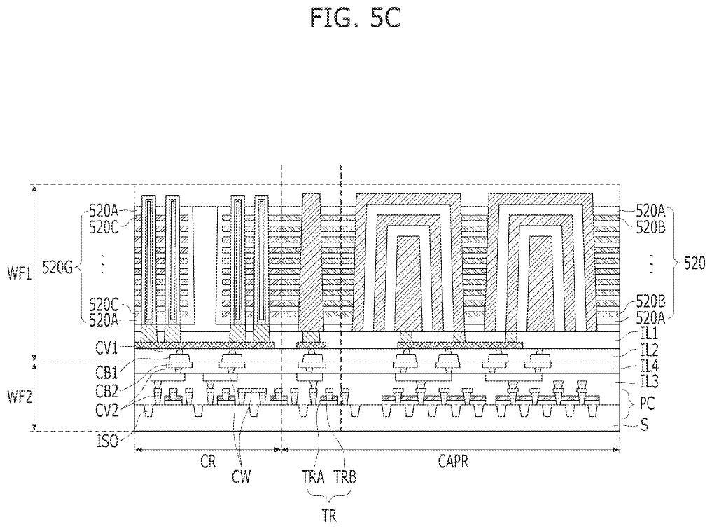

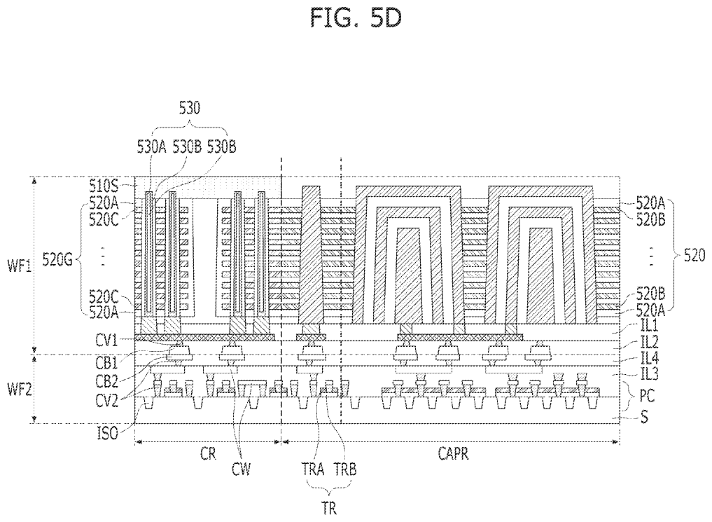

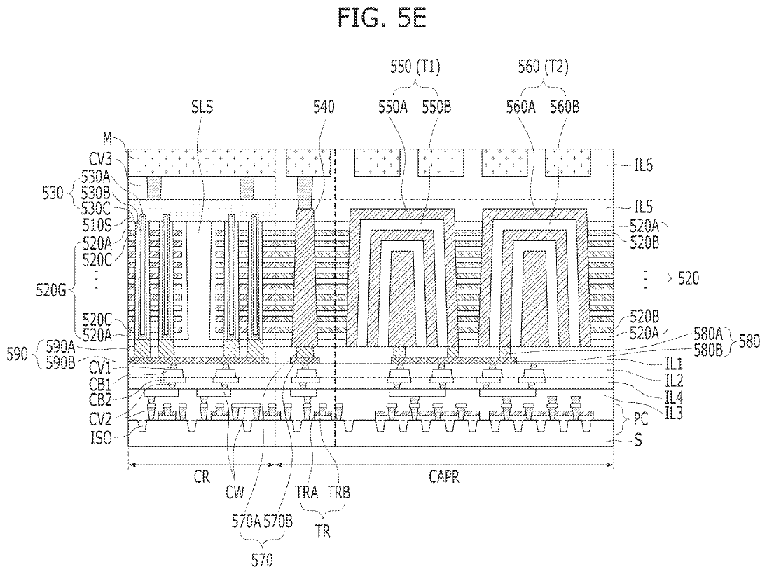

FIGS. 5A to 5E are diagrams illustrating a method of manufacturing a semiconductor device according to an embodiment of the present disclosure. Hereinafter, a description of contents redundant with the aforementioned contents is omitted.

Referring to FIG. 5A, a first wafer WF1 may be formed. In this case, the first wafer WF1 may mean a first semiconductor structure that includes or does not include a substrate. For example, the first wafer WF1 may mean a first semiconductor structure that includes a stack 520, a first capacitor 550, and a second capacitor 560. The first wafer WF1 may further include a substrate 510, a gate structure 520G, the stack 520, channel structures 530, a contact plug 540, the first capacitor 550, the second capacitor 560, a first interconnection structure 570, a second interconnection structure 580, a third interconnection structure 590, a first bonding pad CB1, and a first connection via CV1. The first wafer WF1 may include a cell region CR and a capacitor region CAPR.

The gate structure 520G and the stack 520 may be disposed on the substrate 510. The substrate 510 may include the cell region CR and the capacitor region CAPR. The contact plug 540 may be formed in the capacitor region CAPR and may extend into the substrate 510 through the stack 520. The first interconnection structure 570 may be formed on the contact plug 540. The first interconnection structure 570 may include a first contact via 570A that is connected to the contact plug 540 and may include a first wire 570B that is disposed on the first contact via 570A and connected to the first contact via 570A. The first interconnection structure 570 may be formed within an insulating layer IL1.

The capacitors 550 and 560 may be formed in the capacitor region CAPR and may extend into the substrate 510 through the stack 520. The capacitors 550 and 560 may include conductive layers 550A and 560A and dielectric layers 550B and 560B, respectively, which are alternately stacked. The second interconnection structure 580 may be formed on the capacitors 550 and 560. The second interconnection structure 580 may include a second contact via 580A that is connected to at least one of the conductive layers 550A and 560A of the capacitors 550 and 560 and may include a second wire 580B that is disposed on the second contact via 580A and connected to the second contact via 580A. The second interconnection structure 580 may be formed within the insulating layer IL1.

The channel structures 530 may be formed in the cell region CR and may extend into the substrate 510 through the gate structure 520G. The channel structures 530 may each include at least one of a channel layer 530A, a memory layer 530B that surrounds the channel layer 530A, and an insulating core 530C within the channel layer 530A. The slit structure SLS may be formed within the gate structure 520G. The third interconnection structure 590 may be formed on the channel structures 530. The third interconnection structure 590 may include a third contact via 590A that is connected to the channel structures 530 and a third wire 590B that is connected to at least one of the third contact via 590A.

Next, an insulating layer IL2 may be formed on the insulating layer IL1. Next, first connection vias CV1 that are connected to at least one of the first wire 570B, the second wire 580B, and the third wire 590B through the insulating layer IL2 may be formed. Next, first bonding pads CB1 that are connected to the first connection vias CV1, respectively, may be formed on the first connection vias CV1. The first connection vias CV1 and the first bonding pads CB1 may be formed in the cell region CR and the capacitor region CAPR and may be formed within the insulating layer IL2.

Referring to FIG. 5B, a second wafer WF2 may be formed. In this case, the second wafer WF2 may mean a second semiconductor structure that includes or does not include a substrate. For example, the second wafer WF2 may mean a second semiconductor structure including a peripheral circuit PC. The second wafer WF2 may further include a second connection via CV2, a connection wire CW, or second bonding pads CB2 or may further include the second connection via CV2, the connection wire CW, or the second bonding pads CB2 in combination. The peripheral circuit PC may be formed within an insulating layer IL3 that is formed on a substrate S. The insulating layer IL3 may be formed on the substrate S. An isolation insulating layer ISO may be formed within the substrate S. The peripheral circuit PC may include a transistor TR, a capacitor, a register, and an input and output circuit. The input and output circuit may be a circuit that transmits and receives signals to and from an external device and may include the transistor TR. In this case, the input and output circuit may be disposed in a capacitor region CAPR. The transistor TR may include junctions, a gate insulating layer TRB, or a gate electrode TRA. The gate insulating layer TRB may be disposed between the gate electrode TRA and the substrate S.

The second connection via CV2 may be formed on the substrate S and may be connected to the peripheral circuit PC or may connect the connection wire CW and the second bonding pad CB2. The connection wire CW may connect the second connection vias CV2. The second bonding pads CB2 may be formed on the second connection via CV2 and may be connected to the second connection via CV2. The second bonding pad CB2 may be electrically connected to the peripheral circuit PC through the connection wire CW and the second connection via CV2. The second connection via CV2 or the connection wire CW may be formed within the insulating layer IL3 or the insulating layer IL4. The second bonding pads CB2 may be formed within the insulating layer IL4. The insulating layer IL4 may be formed on the insulating layer IL3.

Next, the first wafer WF1 and the second wafer WF2 may be bonded. For example, the top of the first wafer WF1 and the top of the second wafer WF2 may be bonded. Each of the first bonding pads CB1 and each of the second bonding pads CB2 may be connected. In this case, the capacitors 550 and 560 and the peripheral circuit PC may be bonded so that the capacitors 550 and 560 and the peripheral circuit PC face each other. For example, the first wafer WF1 and the second wafer WF2 may be bonded so that the capacitors 550 and 560 and the input and output circuit face each other. Accordingly, a distance between the capacitors 550 and 560 and the input and output circuit can be reduced because the capacitors 550 and 560 and the input and output circuit are bonded to face each other when the first wafer WF1 and the second wafer WF2 are bonded.

Referring to FIG. 5C, the substrate 510 may be removed. For example, the substrate 510 may be removed so that the channel structures 530 are exposed. In this case, the contact plug 540 and the capacitors 550 and 560 may be exposed. For example, when the substrate 510 is removed, at least one of the contact plug 540 and the conductive layers 550A and 560A of the capacitors 550 and 560 may be exposed.

Referring to FIG. 5D, the channel layer 530A may be exposed by removing a part of the memory layer 530B of each of the channel structures 530. Next, a source structure 510S may be formed. After a source layer is formed in the first wafer WF1, the source structure 510S may be formed by removing the source layer that is formed on the contact plug 540 and the capacitors 550. Accordingly, the source structure 510S that is connected to the channel layer 530A may be formed.

Referring to FIG. 5E, an insulating layer IL5 and an insulating layer IL6 may be formed. Next, a metal wire M may be formed. The metal wire M may be formed on the source structure 510S, the contact plug 540, or the capacitors 550 and 560. The metal wire M may be connected to at least one of the source structure 510S and the contact plug 540 by the third connection via CV3. The metal wire M may be formed within the insulating layer IL6. The metal wire M may include a conductive material, such as copper or aluminum.

According to the aforementioned manufacturing method, the capacitors 550 and 560 may be bonded to face the peripheral circuit PC. Accordingly, a distance between the capacitors 550 and 560 and the input and output circuit can be reduced because the capacitors 550 and 560 and the input and output circuit are bonded to face each other when the first wafer WF1 and the second wafer WF2 are bonded.

Furthermore, the conductive layers 550A and 560A and the dielectric layers 550B and 560B may be alternately stacked within the trenches T1 and T2 by considering the capacitance of the capacitors 350 and 560. The number of conductive layers 550A and 560A may be increased by minimizing the thicknesses of the dielectric layers 550B and 560B. Accordingly, the capacitance of the capacitors 550 and 560 can be increased.

Although embodiments according to the technical spirit of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and change the embodiments in various ways without departing from the technical spirit of the present disclosure written in the claims. Such substitutions, modifications, and changes may be said to belong to the scope of the present disclosure.

What is claimed is:

1. A semiconductor device comprising:
a first semiconductor structure comprising a gate structure and a stack, the gate structure including channel structures and the stack including a capacitor; and
a second semiconductor structure that is bonded to the first semiconductor structure, the second semiconductor structure including a peripheral circuit,
wherein the capacitor comprises conductive layers and dielectric layers that are alternately stacked along an internal surface of a trench that is formed within the stack.

2. The semiconductor device of claim 1, further comprising a contact plug that extends through the stack, the contact plug being connected to the peripheral circuit.

3. The semiconductor device of claim 2, wherein the contact plug has a height that is substantially identical with a height of the capacitor.

4. The semiconductor device of claim 2, wherein the contact plug has a smaller width than the capacitor.

5. The semiconductor device of claim 2, further comprising:
a first contact via that is connected to the contact plug; and
second contact vias that are connected to the conductive layers, respectively.

6. The semiconductor device of claim 5, wherein the first contact via and the second contact vias are disposed under the stack and have heights that are substantially identical with each other.

7. The semiconductor device of claim 5, further comprising:
a first wire that is connected to the first contact via; and
a second wire that is connected to at least one of the second contact vias.

8. The semiconductor device of claim 7, wherein the first wire and the second wire have heights that are substantially identical with each other.

9. The semiconductor device of claim 2, wherein the contact plug and the conductive layers comprise molybdenum.

10. The semiconductor device of claim 1, further comprising a source structure that is disposed on the gate structure, the source structure being connected to the channel structures.

11. The semiconductor device of claim 1, wherein a thickness of each of the conductive layers and the dielectric layers is 300 to 600 Å.

12. The semiconductor device of claim 1,
wherein the peripheral circuit comprises an input and output circuit, and
wherein the input and output circuit faces the capacitor.

13. A semiconductor device comprising:
a stack comprising sacrificial layers and insulating layers that are alternately stacked;
a contact plug that extends through the stack;
a first capacitor that is disposed within the stack, the first capacitor including first conductive layers and first dielectric layers that are alternately stacked;
a second capacitor that is disposed within the stack, the second capacitor including second conductive layers and second dielectric layers that are alternately stacked; and
an interconnection structure that connects the first capacitor and the second capacitor in parallel.

14. The semiconductor device of claim 13,
wherein the first conductive layers comprise an even first conductive layer and an odd first conductive layer, and
wherein the second conductive layers comprise an even second conductive layer and an odd second conductive layer.

15. The semiconductor device of claim 14, wherein the interconnection structure comprises:
a first wire that is connected to the odd first conductive layer and the even second conductive layer; and
a second wire that is connected to the even first conductive layer and the odd second conductive layer.
